(19) United States
(12) Patent Application Publication
(10) Pub. No.: US 2026/0053064 A1
(43) Pub. Date: Feb. 19, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Chih-Chiang HE, Taichung City (TW); Chia-Chen CHIAO, Taichung City (TW); Chun-Sheng CHANG, Taichung City (TW); Chao-Ya YANG, Taichung City (TW)

(21) Appl. No.: 19/004,774

(22) Filed: Dec. 30, 2024

(30) Foreign Application Priority Data
Aug. 19, 2024 (TW) 113131128

(51) Int. Cl. H01L 25/16; H01L 21/48; H01L 21/56; H01L 23/00; H01L 23/367; H01L 23/498; H01L 23/538

(52) U.S. Cl. CPC H01L 25/162; H01L 21/4853; H01L 21/56; H01L 23/3675; H01L 23/49811; H01L 23/5385; H01L 23/5386; H01L 24/32; H01L 24/48; H01L 24/16; H01L 24/73; H01L 2224/16227; H01L 2224/32225; H01L 2224/32245; H01L 2224/48221; H01L 2224/73204; H01L 2225/0651; H01L 2924/19105

(57) ABSTRACT

An electronic package and a manufacturing method thereof are provided, including a first electronic component disposed on a first side of a first substrate disposed on a first surface of a circuit board, a plurality of bonding wires formed on the first side of the first substrate for electrically connecting the first substrate to the circuit board. A second electronic component is disposed on the first surface of the circuit board for the first electronic component to be electrically connected to the second electronic component via the first substrate, the plurality of bonding wires and the circuit board in sequence. A first encapsulant is formed on the first surface of the circuit board to cover the first substrate, the first electronic component and the plurality of bonding wires. Thereby, the present disclosure can effectively reduce the size of the first substrate and the electronic package.

### CROSS-REFERENCE TO RELATED APPLICATIONS

The present application is based upon and claims the right of priority to TW Patent Application No. 113131128, filed Aug. 19, 2024, the disclosure of which is hereby incorporated by reference herein in its entirety for all purposes

### BACKGROUND

### 1. Technical Field

The present disclosure relates to a semiconductor packaging technology, and more particularly, to an electronic package and a manufacturing method thereof.

### 2. Description of Related Art

In recent years, with the continuous maturity and development of semiconductor process technology, various high-performance electronic products have been continuously introduced. The functions of electronic products are developing towards humanization and multi-function, and there are various integrated circuit (IC) elements with different functions inside electronic products.

In the manufacturing process of electronic components, integrated circuit packaging (IC packaging) plays a very important role, and integrated circuit packaging types can be roughly divided into two categories: pin in hole (PIH) and surface mount technology (SMT). For example, the pin in hole type can be a dual in-line package (DIP) and a pin grid array package (Pin Grid Array; PGA), the surface mount technology type can be wire bonding (WB) package, tape automatic bonding (TAB) package, flip chip bonding (Flip Chip; FC) and ball grid array package (BGA) and other types, and each package form has its own particularities and application areas. Therefore, the industry developed the idea of stacking the aforementioned different package units to form a stacked package structure (Package on Package; PoP) as shown in FIG. 1 below, thereby increasing electrical performance to meet future product needs.

FIG. 1 is a schematic cross-sectional view of a stacked package structure 1 of the prior art. As shown in FIG. 1, the manufacturing method of the stacked package structure 1 may include: providing a substrate 10 (such as a BGA substrate) with a plurality of solder pads 11 on an upper surface of the substrate 10, disposing a semiconductor chip 12 on the substrate 10 and forming an encapsulant 13 to cover the semiconductor chip 12 to form a first semiconductor package 14. Then, a packaged second semiconductor package 15 is bonded to and electrically connected to the plurality of solder pads 11 of the substrate 10 of the first semiconductor package 14 via a plurality of solder balls 16 by a reflow operation, thereby forming the stacked package structure 1.

However, when the stacked package structure 1 is used in today's consumer electronics products (such as smartphones) for responding to the high-speed networking and computing needs of the future fifth generation (5G) and artificial intelligence (AI), processors (such as application processors (APs)) of consumer electronic products require higher and higher performance, so the demand for memory is also getting higher and higher. At the same time, as the size of the memory increases, overall height of the stacked package structure 1 will also become thicker. The increase in the computing speed of the processor also creates higher heat dissipation requirements. Therefore, the industry has introduced a side-by-side package structure 2 as shown in FIG. 2A and FIG. 2B to simultaneously solve the height (thickness) and heat dissipation problems of the stacked package structure 1 as shown in FIG. 1.

FIG. 2A and FIG. 2B are respectively a schematic cross-sectional view and a schematic top view of the side-by-side package structure 2 of the prior art. As shown in FIG. 2A and FIG. 2B, the side-by-side package structure 2 mainly includes a circuit board 20, a substrate 21, a substrate 22, a processor 23 and two memories 24. The substrate 21 and the substrate 22 are arranged in a side-by-side manner on left and right sides of the circuit board 20 via a plurality of solder balls 25 and a plurality of solder balls 26 (such as tin balls), respectively. The processor 23 is disposed on the substrate 21 via a plurality of conductive elements 27, and the memories 24 are disposed on the substrate 22 and are electrically connected to the substrate 22 via a plurality of bonding wires 28. Thereby, signals of the processor 23 can be sequentially brought out via a signal transmission path P composed of the conductive elements 27, the substrate 21, the solder balls 25, the circuit board 20, the solder balls 26 and the bonding wires 28 to be electrically connected to the memories 24.

Although the side-by-side package structure 2 can solve the height (thickness) and heat dissipation problems of the stacked package structure 1 in FIG. 1, the side-by-side arrangement of the side-by-side package structure 2 would cause the problem of enlarging the area, and thus the side-by-side package structure 2 cannot meet the needs of future products that are light, thin, short, and small.

Furthermore, the connection of the plurality of solder balls 25 in the side-by-side package structure 2 requires more solder balls 25 due to a large number of connection signals between the processor 23 and the memories 24. Moreover, each solder ball 25 requires a larger size or pitch, which causes the size (such as lengths A or areas) of the substrate 21 to become larger, thereby the overall size and cost of the side-by-side package structure 2 is increased.

Therefore, how to overcome the above problems of the prior art has become an urgent problem to be solved.

### SUMMARY

In view of the various deficiencies of the prior art, the present disclosure provides an electronic package, which comprises: a first substrate having a first side and a second side opposite to the first side; a first electronic component disposed on the first side of the first substrate; a circuit board having a first surface and a second surface opposite to the first surface, wherein the first substrate is disposed on the first surface of the circuit board, and wherein a plurality of bonding wires are formed on the first side of the first substrate for electrically connecting the first substrate to the circuit board; a second electronic component disposed on the first surface of the circuit board, in a manner that the first electronic component is electrically connected to the second electronic component via the first substrate, the plurality of bonding wires and the circuit board in sequence; and a first encapsulant formed on the first surface of the circuit board to encapsulate the first substrate, the first electronic component and the plurality of bonding wires.

The present disclosure further provides a method of manufacturing an electronic package, the method comprises: providing a first substrate having a first side and a second side opposite to the first side for a first electronic component to be disposed on the first side of the first substrate; providing a circuit board having a first surface and a second surface opposite to the first surface for the first substrate to be disposed on the first surface of the circuit board, and wherein a plurality of bonding wires are formed on the first side of the first substrate, and the first substrate is electrically connected to the circuit board via the plurality of bonding wires; disposing a second electronic component on the first surface of the circuit board, and electrically connecting the first electronic component to the second electronic component via the first substrate, the plurality of bonding wires and the circuit board in sequence; and forming a first encapsulant on the first surface of the circuit board to encapsulate the first substrate, the first electronic component and the plurality of bonding wires.

In the aforementioned electronic package and method, an upper surface of the first encapsulant is higher than an upper surface of the first electronic component.

In the aforementioned electronic package and method, an upper surface of the first encapsulant is flush with or exposed from an upper surface of the first electronic component.

In the aforementioned electronic package and method, which comprises disposing a second substrate on the first surface of the circuit board, disposing the second electronic component on the second substrate, and then forming a second encapsulant on the second substrate to encapsulate the second electronic component.

In the aforementioned electronic package and method, which comprises forming a heat dissipation member on an upper surface of the first electronic component, wherein the first encapsulant further encapsulates the heat dissipation member, and an upper surface of the heat dissipation member is flush with or exposed from the upper surface of the first encapsulant.

In the aforementioned electronic package and method, which further comprises forming an adhesion layer on an upper surface of the first electronic component, an upper surface of the second electronic component and an upper surface of the first encapsulant.

In the aforementioned electronic package and method, which further comprises forming an adhesion layer on an upper surface of the first electronic component and an upper surface of the first encapsulant.

In the aforementioned electronic package and method, which further comprises disposing at least one passive element on the first side or the second side of the first substrate.

In the aforementioned electronic package and method, which further comprises disposing an interposer on the first surface of the circuit board, wherein the plurality of bonding wires are formed between the first side of the first substrate and an upper surface of the interposer, and the upper surface of the interposer is lower than or higher than the first side of the first substrate.

In the aforementioned electronic package and method, the first encapsulant further encapsulates the second electronic component.

It can be seen from the above that in the electronic package and the manufacturing method thereof of the present disclosure, bonding wires with smaller sizes or pitches are formed between the first substrate and the circuit board (or the interposer), which is beneficial for reducing the size (such as lengths or areas) of the first substrate, and can also reduce the overall size (such as volume) of electronic packages.

Alternatively, the electronic package of the present disclosure adopts a connection method of the plurality of bonding wires because the plurality of bonding wires only require a smaller size or pitch. Therefore, the size of the required first substrate can be effectively reduced, thereby reduction on the overall size and cost of the electronic package can be achieved.

Or, the present disclosure can form the heat dissipation member on the upper surface of the first electronic component, so as to use the heat dissipation member to quickly dissipate the heat energy generated by the first electronic component to an outside for heat dissipation or cooling.

Alternatively, the present disclosure can utilize the adhesion layer to quickly dissipate the heat energy generated by the first electronic component and the second electronic component to the outside for heat dissipation or cooling, or may use the adhesion layer to effectively shield the signals generated by both the first electronic component and the second electronic component, to block the first electronic component and the second electronic component from external signal interference or electromagnetic interference (EMI).

Furthermore, the present disclosure can utilize the adhesion layer to quickly dissipate the heat energy generated by the first electronic component to the outside for heat dissipation, or may use the adhesion layer to effectively shield the signals generated by both the first electronic component and the second electronic component to block the first electronic component and the second electronic component from signal interference or electromagnetic interference (EMI).

In addition, the interposer in the present disclosure can be disposed between the first substrate (the first electronic component) and the second electronic component, then the plurality of bonding wires are formed between the circuit layer of the first substrate and the upper surface of the interposer, and the upper surface of the interposer can be lower or higher than the first side of the first substrate. Therefore, the bonding wires would not contact the material of the solder balls (such as tin material) on the circuit board, thereby adverse effects (such as tin material contamination or electrical short circuit) on the bonding wires by the material of the solder balls (such as tin material) can be prevented.

### BRIEF DESCRIPTION OF THE DRAWINGS

FIG. 1 is a schematic cross-sectional view of a stacked package structure of the prior art.

FIG. 2A and FIG. 2B are respectively a schematic cross-sectional view and a schematic top view of a side-by-side package structure of the prior art.

FIG. 3A to FIG. 3F are schematic cross-sectional views illustrating a manufacturing method of an electronic package according to a first embodiment of the present disclosure, and FIG. 3F-1 is a schematic top view of the electronic package in FIG. 3F.

FIG. 4 is a schematic cross-sectional view of the electronic package according to a second embodiment of the present disclosure.

FIG. 5 is a schematic cross-sectional view of the electronic package according to a third embodiment of the present disclosure.

FIG. 6 is a schematic cross-sectional view of the electronic package according to a fourth embodiment of the present disclosure.

FIG. 7 is a schematic cross-sectional view of the electronic package according to a fifth embodiment of the present disclosure.

FIG. 8 is a schematic cross-sectional view of the electronic package according to a sixth embodiment of the present disclosure.

FIG. 9 is a schematic cross-sectional view of the seventh embodiment of the electronic package of the present disclosure.

FIG. 10 is a schematic cross-sectional view of the electronic package according to an eighth embodiment of the present disclosure.

FIG. 11 is a schematic cross-sectional view of the electronic package according to a ninth embodiment of the present disclosure.

FIG. 12 is a schematic cross-sectional view of the electronic package according to a tenth embodiment of the present disclosure.

FIG. 13 is a schematic cross-sectional view of the electronic package according to an eleventh embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “below,” “lower,” “one,” “two,” “first,” “second,” “third” and the like are merely used for clear explanation rather than limiting the practicable scope of the present disclosure, and thus, alterations or adjustments of the relative relationships thereof without essentially altering the technical contents should still be considered in the practicable scope of the present disclosure.

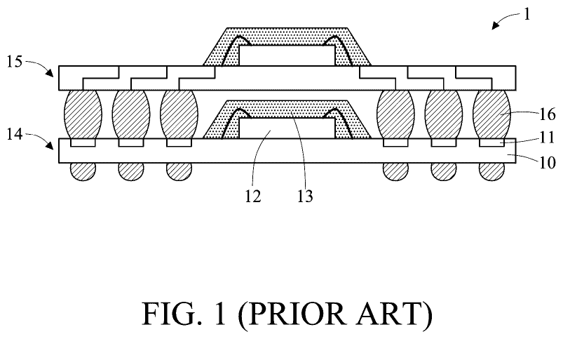

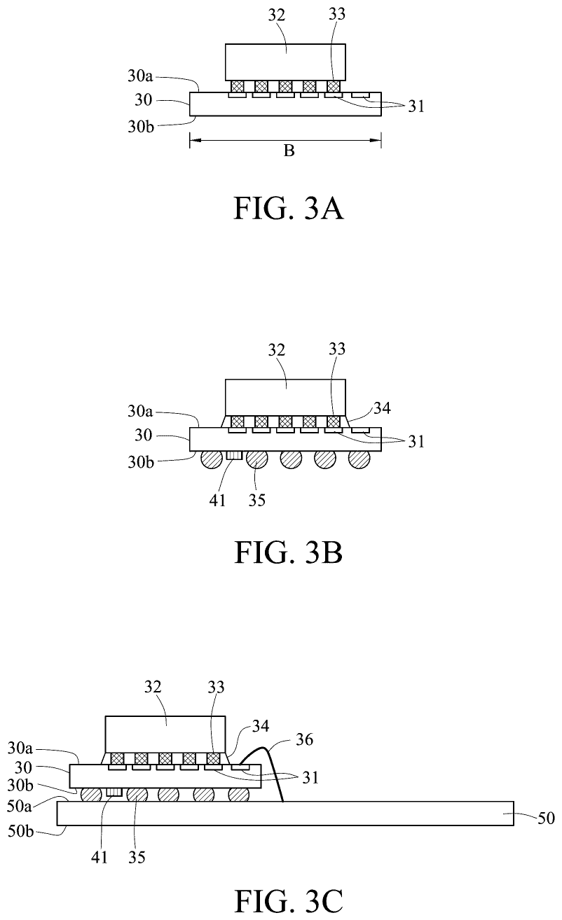

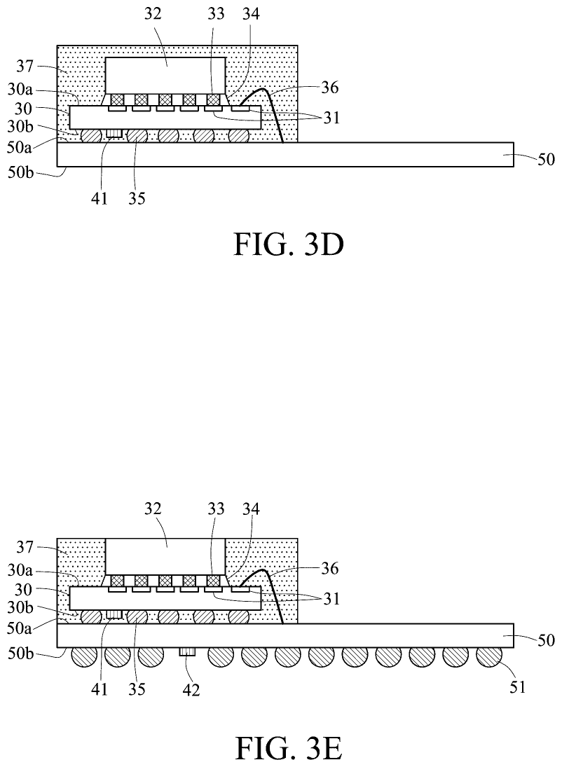

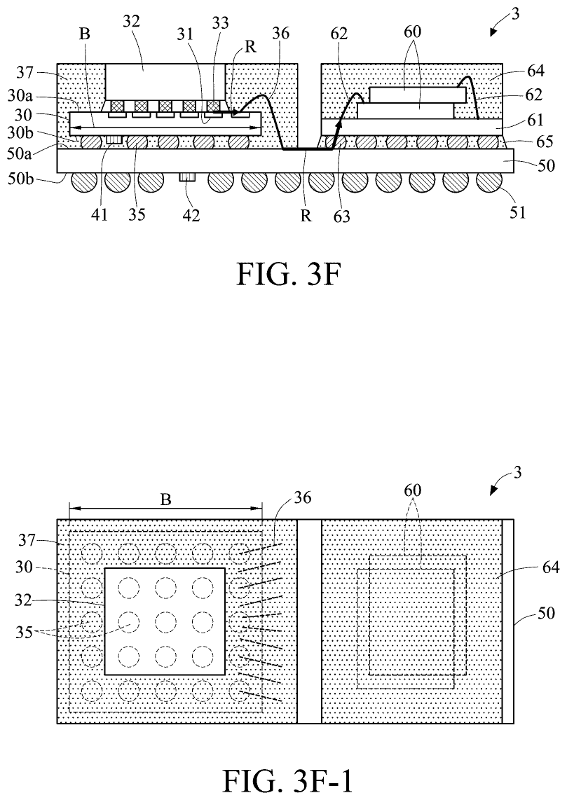

FIG. 3A to FIG. 3F are schematic cross-sectional views illustrating a manufacturing method of an electronic package 3 according to the first embodiment of the present disclosure, and FIG. 3F-1 is a schematic top view of the electronic package 3 in FIG. 3F. At the same time, the term “at least one” in the present disclosure represents more than one (such as one, two or three), and the term “plurality” represents more than two (such as two, three, four or more than ten).

As shown in FIG. 3A, a first substrate 30 having a first side 30a and a second side 30b opposite to the first side 30a and at least one circuit layer 31 is provided, and the circuit layer 31 may be formed on the first side 30a of the first substrate 30. Next, at least one first electronic component 32 is disposed on the first side 30a of the first substrate 30 (such as soldering pads of the circuit layer 31) via a plurality of conductive elements 33. Therefore, the plurality of conductive elements 33 are disposed between the first side 30a of the first substrate 30 (such as the soldering pads of the circuit layer 31) and a lower surface (such as an active surface) of the first electronic component 32, thereby the first electronic component 32 is electrically connected to the circuit layer 31 of the first substrate 30 via the plurality of conductive elements 33.

In one embodiment, the electronic package 3 may be a side-by-side package structure and the like, the first substrate 30 may be a package substrate, a carrier board, a circuit board and the like, the circuit layer 31 may be a redistribution layer (RDL) and the like, the first electronic component 32 may be a processor (such as an application processor), a semiconductor chip and the like, and the conductive element 33 may be a conductor, a conductive bump, a conductive contact, a solder ball, a tin ball and the like.

As shown in FIG. 3B, an underfill 34 is formed between the first side 30a of the first substrate 30 and a lower surface (such as an active surface) of the first electronic component 32 to cover the plurality of conductive elements 33. A plurality of solder balls 35 are also formed on the second side 30b of the first substrate 30, and at least one (for example, a plurality of) passive element 41 is disposed on the second side 30b of the first substrate 30.

In one embodiment, the underfill 34 can be an underfill material and the like, the solder balls 35 can be tin balls, metal balls and the like, and the passive element 41 can be a resistor, a capacitor, an inductor and the like.

As shown in FIG. 3C, a circuit board 50 having a first surface 50a and a second surface 50b opposite to the first surface 50a is provided, so that a structure composed of the first substrate 30, the first electronic component 32, the conductive elements 33, the underfill 34, the solder balls 35 and the passive element 41 in FIG. 3B is disposed on the first surface 50a of the circuit board 50 (such as one side or left side of the first surface 50a). Then, a plurality of bonding wires 36 are disposed between the circuit layer 31 (for example, the rightmost soldering pad of circuit layer 31) on the first side 30a of the first substrate 30 and the first surface 50a of the circuit board 50 by a wire bonding (WB) process, so that the circuit layer 31 of the first substrate 30 is electrically connected to the circuit board 50 via the plurality of bonding wires 36.

In one embodiment, the bonding wires 36 may be metal wires, copper wires, gold wires and the like, and the circuit board 50 may be a carrier board, a carrier, or a carrier substrate having at least one (e.g., plural) circuit layer and the like.

As shown in FIG. 3D, a first encapsulant 37 is formed on at least a portion (such as the left half) of the first surface 50a of the circuit board 50, so that the first substrate 30, the first electronic component 32, the plurality of bonding wires 36, the underfill 34, the plurality of solder balls 35, the passive element 41, etc. are covered by the first encapsulant 37. At the same time, a height of an upper surface of the first encapsulant 37 can be higher than a height of an upper surface (such as the non-active surface) of the first electronic component 32. Therefore, the first encapsulant 37 covers the upper surface of the first electronic component 32, and the upper surface of the first electronic component 32 is not exposed from an upper surface of the first encapsulant 37.

As shown in FIG. 3E, a portion of the first encapsulant 37 in FIG. 3D is removed by a leveling process (such as grinding, cutting or etching) to thin the thickness of the first encapsulant 37. Accordingly, the upper surface (such as the non-active surface) of the first electronic component 32 and the upper surface of the first encapsulant 37 are coplanar, or the upper surface of the first electronic component 32 is flush with or exposed from the upper surface of the first encapsulant 37, and the first encapsulant 37 does not cover the upper surface of the first electronic component 32. A plurality of conductors 51 are also disposed on the second surface 50b of the circuit board 50, and at least one (e.g., a plurality of) passive element 42 is disposed on the second surface 50b of the circuit board 50.

In one embodiment, the conductors 51 can be conductive elements, conductive bumps, conductive contacts, solder balls, solder balls and the like, and the passive element 42 can be a resistor, a capacitor, an inductor and the like.

As shown in FIG. 3F and FIG. 3F-1, at least one (such as two) second electronic component 60 is first disposed on an upper surface of a second substrate 61, and a plurality of bonding wires 62 can be formed between an upper surface (such as the active surface) of the second electronic component 60 and the upper surface of the second substrate 61 via a wire bonding method or a wire bonding (WB) process. As such, the second substrate 61 is electrically connected to the second electronic component 60 via the plurality of bonding wires 62, a second encapsulant 64 can be formed on the upper surface of the second substrate 61 to cover the second electronic component 60 and the plurality of bonding wires 62, and then the second substrate 61 is disposed on the first surface 50a of the circuit board 50 (such as another side or right side of the first surface 50a) via a plurality of solder balls 63. Alternatively, the second substrate 61 is first disposed on the first surface 50a of the circuit board 50 (such as the other side or right side of the first surface 50a) via the plurality of solder balls 63, then at least one (e.g., two) second electronic component 60 is disposed on the upper surface of the second substrate 61, the plurality of bonding wires 62 are disposed, and the second encapsulant 64 is formed.

Thereby, the first electronic component 32 and the second electronic component 60 are respectively located on both sides (such as the left and right sides) of the first surface 50a of the circuit board 50 in a side-by-side manner, and the plurality of bonding wires 36 may be between the first electronic component 32 (the first substrate 30) and the second electronic component 60 (the second substrate 61), that is, the plurality of bonding wires 36 may be adjacent to the second electronic component 60 (the second substrate 61).

In addition, an underfill 65 can be formed between the first surface 50a of the circuit board 50 and a lower surface of the second substrate 61 to cover the plurality of solder balls 63.

In one embodiment, the second electronic component 60 may be a memory, a semiconductor chip and the like, the second substrate 61 can be a package substrate, a carrier board, a circuit board and the like, the bonding wires 62 can be metal wires, copper wires, gold wires and the like, the solder ball 63 can be a tin ball, a metal ball and the like, and the underfill 65 can be an underfill material and the like.

Therefore, in the embodiment of FIG. 3F and FIG. 3F-1, signals of the first electronic component 32 can be passed through a “signal transmission path R” composed of the conductive elements 33, the first substrate 30, the bonding wires 36, the circuit board 50, the solder balls 63, the second substrate 61 and the bonding wires 62 in sequence for electrical connection to the second electronic component 60.

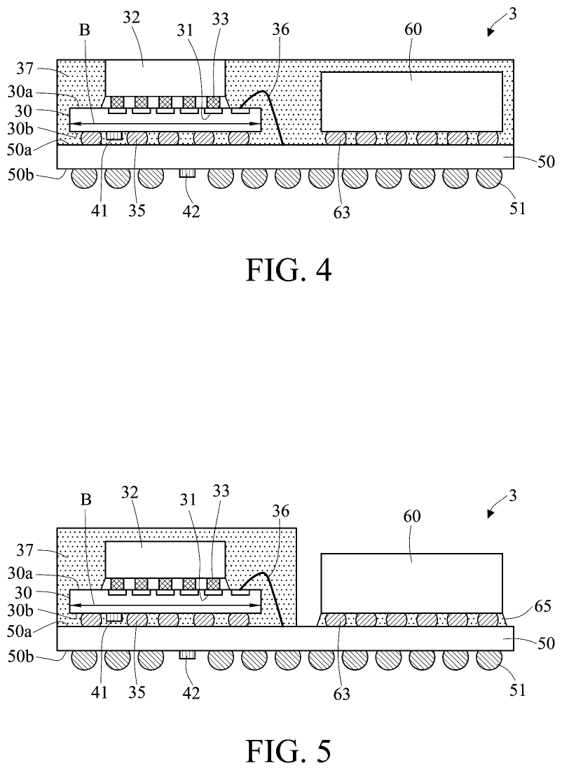

FIG. 4 is a schematic cross-sectional view of the electronic package 3 according to the second embodiment of the present disclosure, and FIG. 5 is a schematic cross-sectional view of the electronic package 3 according to the third embodiment of the present disclosure. The main differences between the electronic package 3 in FIG. 4 and FIG. 5 and the electronic package 3 in FIG. 3F are as follows, and the remaining contents are the same and are omitted herein.

As shown in FIG. 4, the first encapsulant 37 can directly cover a second electronic component 60 and the plurality of solder balls 63, and thus the second encapsulant 64 is omitted in FIG. 3F.

As shown in FIG. 5, the height of the upper surface of the first encapsulant 37 can be higher than the height of the upper surface (such as the non-active surface) of the first electronic component 32. Therefore, the first encapsulant 37 covers the upper surface of the first electronic component 32, and the upper surface of the first electronic component 32 is not exposed from the upper surface of the first encapsulant 37.

In the embodiments of FIG. 4 and FIG. 5, the second electronic component 60 can be directly disposed on the first surface 50a of the circuit board 50 via the plurality of solder balls 63, and thus the second substrate 61 and the bonding wires 62 are omitted in FIG. 3F. That is, the signals of the first electronic component 32 can only be passed through the signal transmission path R (see FIG. 3F) composed of the conductive elements 33, the first substrate 30 (the circuit layer 31), the bonding wires 36, the circuit board 50 and the solder balls 63 in sequence for electrical connection of the second electronic component 60. On the contrary, signals of the second electronic component 60 can also only be passed through a “reverse signal transmission path R” composed of the solder balls 63, the circuit board 50, the bonding wires 36, the first substrate 30 (the circuit layer 31) and the conductive elements 33 in sequence for electrical connection of the first electronic component 32.

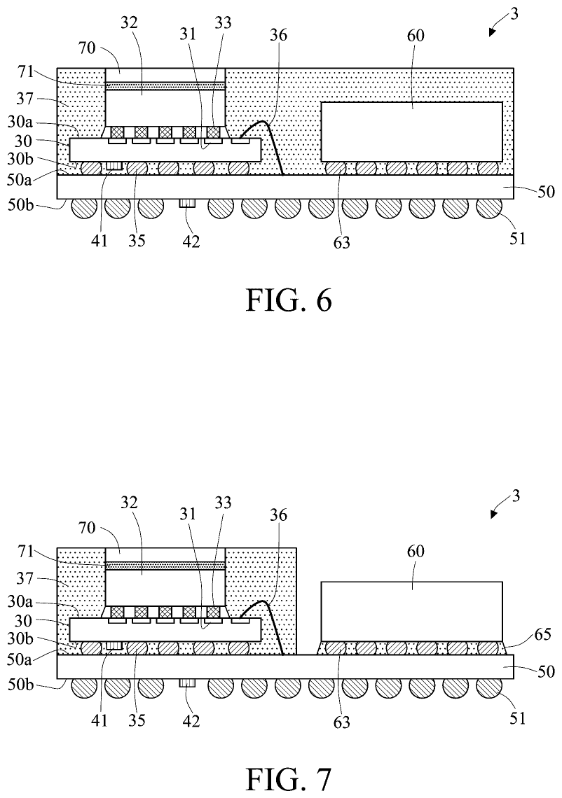

FIG. 6 is a schematic cross-sectional view of the electronic package 3 according to the fourth embodiment of the present disclosure, and FIG. 7 is a schematic cross-sectional view of the electronic package 3 according to the fifth embodiment of the present disclosure. The main differences between the electronic package 3 in FIG. 6 and FIG. 7 and the electronic package 3 in FIG. 4 and FIG. 5 are as follows.

As shown in FIG. 6 and FIG. 7, a heat dissipation member 70 can be disposed on the upper surface (such as the non-active surface) of the first electronic component 32, or the heat dissipation member 70 can be bonded to the upper surface of the first electronic component 32 via a bonding layer 71, so that the heat dissipation member 70 is used to quickly dissipate the heat energy generated by the first electronic component 32 to an outside for heat dissipation or cooling. At the same time, the first encapsulant 37 can further cover the heat dissipation member 70 and the bonding layer 71, and an upper surface of the heat dissipation member 70 can be flush with or exposed from the upper surface of the first encapsulant 37.

In one embodiment, the heat dissipation member 70 can be a heat dissipation colloid, a heat dissipation sheet and the like, or a metal layer, a metal sheet and the like that has a heat dissipation function, and the bonding layer 71 may be a bonding colloid, an adhesion layer and the like.

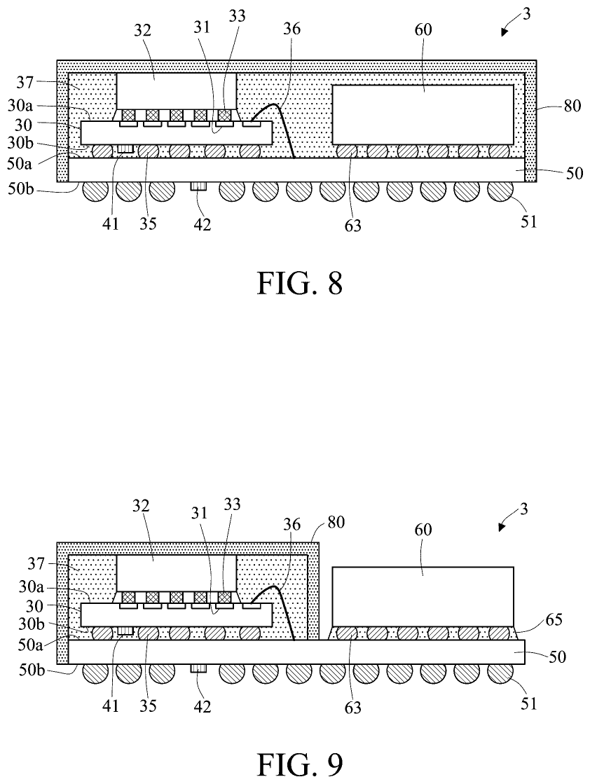

FIG. 8 is a schematic cross-sectional view of the electronic package 3 according to the sixth embodiment of the present disclosure, and FIG. 9 is a schematic cross-sectional view of the electronic package 3 according to the seventh embodiment of the present disclosure. The main differences between the electronic package 3 in FIG. 8 and FIG. 9 and the electronic package 3 in FIG. 4 and FIG. 5 are as follows.

As shown in FIG. 8, an adhesion layer 80 (a heat dissipation layer or a shielding layer) can be formed on the upper surface (such as non-active surface) of the first electronic component 32, the upper surface of the second electronic component 60, and the upper surface to side surfaces of the first encapsulant 37. The adhesion layer 80 can also be further extended to the side surfaces of the circuit board 50, and the adhesion layer 80 can directly contact the upper surface of the first electronic component 32 and/or the second electronic component 60.

Therefore, the present disclosure can utilize the adhesion layer 80 to quickly dissipate the heat energy generated by the first electronic component 32 and the second electronic component 60 to an outside for heat dissipation or cooling. Alternatively, the adhesion layer 80 may be used to effectively shield the signals generated by the first electronic component 32 and the second electronic component 60 to block the first electronic component 32 and the second electronic component 60 from external signal interference or electromagnetic interference (EMI).

As shown in FIG. 9, the adhesion layer 80 can be formed on the upper surface (such as the non-active surface) of the first electronic component 32 and the upper surface to the side surfaces of the first encapsulant 37, wherein the adhesion layer 80 can also be further extended to the side surfaces of the circuit board 50, and the adhesion layer 80 can directly contact the upper surface of the first electronic component 32.

Therefore, the present disclosure can utilize the adhesion layer 80 to quickly dissipate the heat energy generated by the first electronic component 32 to the outside for heat dissipation. Alternatively, the adhesion layer 80 may be used to effectively shield the signals generated by the first electronic component 32 and the second electronic component 60 to block the first electronic component 32 and the second electronic component 60 from signal interference or electromagnetic interference (EMI).

In one embodiment, the adhesion layer 80 can be a heat dissipation colloid, a heat dissipation sheet, a heat dissipation member, a signal shielding layer, an electromagnetic shielding layer and the like, or a metal layer or metal element having heat dissipation or shielding functions.

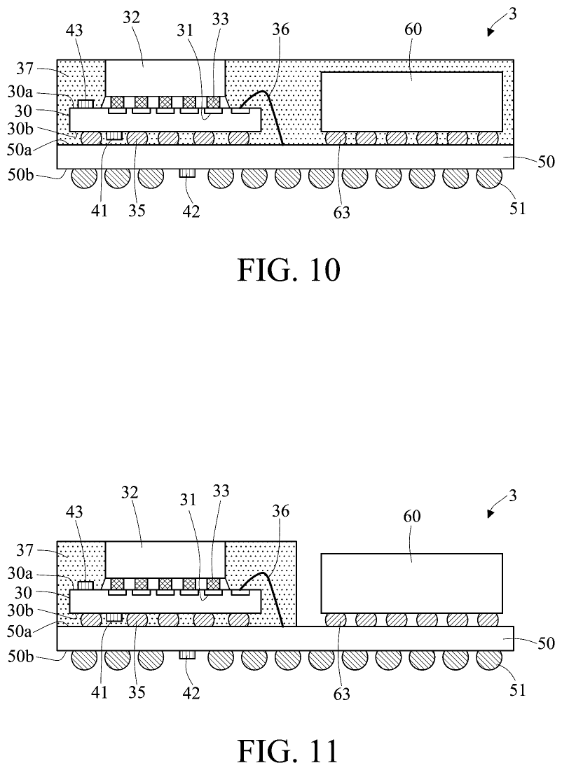

FIG. 10 is a schematic cross-sectional view of the electronic package 3 according to the eighth embodiment of the present disclosure, and FIG. 11 is a schematic cross-sectional view of the electronic package 3 according to the ninth embodiment of the present disclosure The main differences between the electronic package 3 in FIG. 10 and FIG. 11 and the electronic package 3 in FIG. 4 and FIG. 5 are as follows.

As shown in FIG. 10 and FIG. 11, at least one (e.g., plural) passive element 43 can be disposed on the first side 30a of the first substrate 30 to make a good use of available area on the first side 30a of the first substrate 30 to increase a number of passive elements 43, thereby the electrical function can be improved.

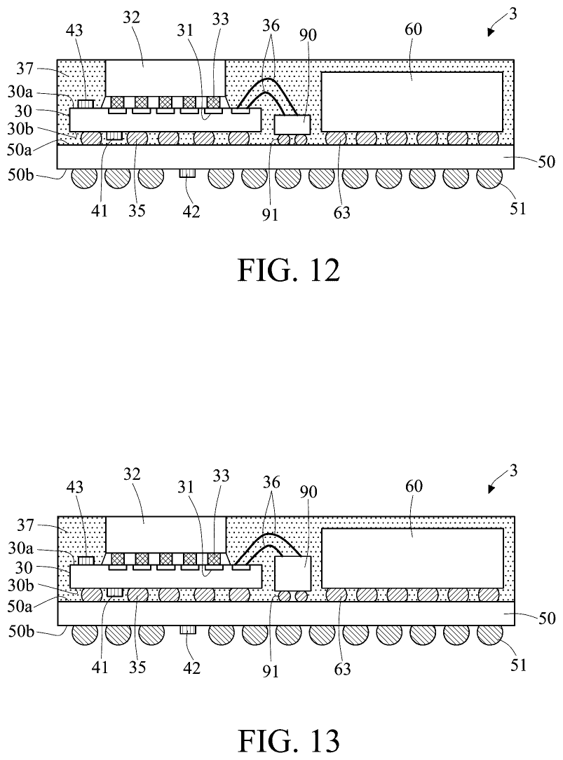

FIG. 12 is a schematic cross-sectional view of the electronic package 3 according to the tenth embodiment of the present disclosure, and FIG. 13 is a schematic cross-sectional view of the electronic package 3 according to the eleventh embodiment of the present disclosure. The main differences between the electronic package 3 in FIG. 12 and FIG. 13 and the electronic package 3 in FIG. 10 and FIG. 11 are as follows.

As shown in FIG. 12 and FIG. 13, an interposer 90 can be disposed on the first surface 50a of the circuit board 50 via a plurality of solder balls 91, the interposer 90 is thus interposed between the first substrate 30 (the first electronic component 32) and the second electronic component 60, and the interposer 90 is electrically connected to the circuit board 50 via the plurality of solder balls 91. Then, the plurality of bonding wires 36 are formed between the first side 30a (the circuit layer 31) of the first substrate 30 and an upper surface of the interposer 90 by a wire bonding method or a wire bonding (WB) process, so that the first substrate 30 (the circuit layer 31) is electrically connected to the circuit board 50 via the plurality of bonding wires 36, the interposer 90 and the plurality of solder balls 91 in sequence.

In the embodiment of FIG. 12, an height of the upper surface of the interposer 90 may be lower than a height of the first side 30a (such as the upper surface) of the first substrate 30. In the embodiment of FIG. 13, the height of the upper surface of the interposer 90 may be higher than the height of the first side 30a (such as the upper surface) of the first substrate 30.

Therefore, the present disclosure can provide the interposer 90 between the first substrate 30 (the first electronic component 32) and the second electronic component 60 to bond the plurality of bonding wires 36 to the upper surface of the interposer 90. Therefore, the bonding wires 36 would not contact the materials (such as tin materials) of the solder balls 35 or the solder balls 63 on the first surface 50a of the circuit board 50, thereby adverse effects (such as tin material contamination or electrical short circuit) on the bonding wires 36 by the materials (such as tin materials) of the solder balls 35 or the solder balls 63 can be prevented.

The first electronic component 32 can be electrically connected to the second electronic component 60 via the conductive elements 33, the circuit layer 31 of the first substrate 30 (such as the rightmost soldering pad of the circuit layer 31), the bonding wires 36, the interposer 90, the solder balls 91, the circuit board 50 and a leftmost solder ball 63 in sequence. On the contrary, the second electronic component 60 can also be electrically connected to the first electronic component 32 via the leftmost solder ball 63, the circuit board 50, the solder balls 91, the interposer 90, the bonding wires 36, the circuit layer 31 of the first substrate 30 (such as a rightmost soldering pad of the circuit layer 31) and the conductive elements 33 in sequence.

In one embodiment, the interposer 90 can be a substrate, a carrier board, a circuit board, a conductive and the like that has a circuit layer or electrical connection function, and the solder balls 91 may be solder balls, metal balls, conductors, conductive bumps and the like.

The present disclosure also provides the electronic package 3 including: the first substrate 30 having the first side 30a and the second side 30b opposite to the first side 30a; the first electronic component 32 disposed on the first side 30a of the first substrate 30; the circuit board 50 having the first surface 50a and the second surface 50b opposite to the first surface 50a, wherein the first substrate 30 is disposed on the first surface 50a of the circuit board 50, and wherein the plurality of bonding wires 36 are formed on the first side 30a of the first substrate 30, and the first substrate 30 is electrically connected to the circuit board 50 via the plurality of bonding wires 36; at least one second electronic component 60 disposed on the first surface 50a of the circuit board 50, wherein the first electronic component 32 is electrically connected to the second electronic component 60 via the first substrate 30, the plurality of bonding wires 36 and the circuit board 50 in sequence; and the first encapsulant 37 formed on the first surface 50a of the circuit board 50 to cover the first substrate 30, the first electronic component 32 and the plurality of bonding wires 36.

In one embodiment, the upper surface of the first encapsulant 37 is higher than the upper surface of the first electronic component 32, and the first encapsulant 37 covers the upper surface of the first electronic component 32.

In one embodiment, the upper surface of the first encapsulant 37 is flush with or exposed from the upper surface of the first electronic component 32, and the first encapsulant 37 does not cover the upper surface of the first electronic component 32.

In one embodiment, the electronic package 3 may include the second substrate 61 and the second encapsulant 64, wherein the second substrate 61 is disposed on the first surface 50a of the circuit board 50, the second electronic component 60 is disposed on the second substrate 61, and the second encapsulant 64 is formed on the second substrate 61 to cover the second electronic component 60.

In one embodiment, the electronic package 3 may include the heat dissipation member 70 formed on the upper surface of the first electronic component 32, wherein the first encapsulant 37 further covers the heat dissipation member 70, and the upper surface of the heat dissipation member 70 is flush with or exposed from the upper surface of the first encapsulant 37.

In one embodiment, the electronic package 3 may include the adhesion layer 80 formed on the upper surface of the first electronic component 32, the upper surface of the second electronic component 60, and the upper surface of the first encapsulant 37.

In one embodiment, the electronic package 3 may include the adhesion layer 80 formed on the upper surface of the first electronic component 32 and the upper surface of the first encapsulant 37.

In one embodiment, the electronic package 3 may include at least one passive element 43 disposed on the first side 30a of the first substrate 30. At the same time, the electronic package 3 may also include at least one passive element 41 disposed on the second side 30b of the first substrate 30.

In one embodiment, the electronic package 3 may include the interposer 90 disposed on the first surface 50a of the circuit board 50, wherein the plurality of bonding wires 36 are formed between the first side 30a of the first substrate 30 and the upper surface of the interposer 90, and the upper surface of the interposer 90 is lower than the first side 30a of the first substrate 30.

In one embodiment, the electronic package 3 may include an interposer 90 disposed on the first surface 50a of the circuit board 50, wherein the plurality of bonding wires 36 are formed between the first side 30a of the first substrate 30 and the upper surface of the interposer 90, and the upper surface of the interposer 90 is higher than the first side 30a of the first substrate 30.

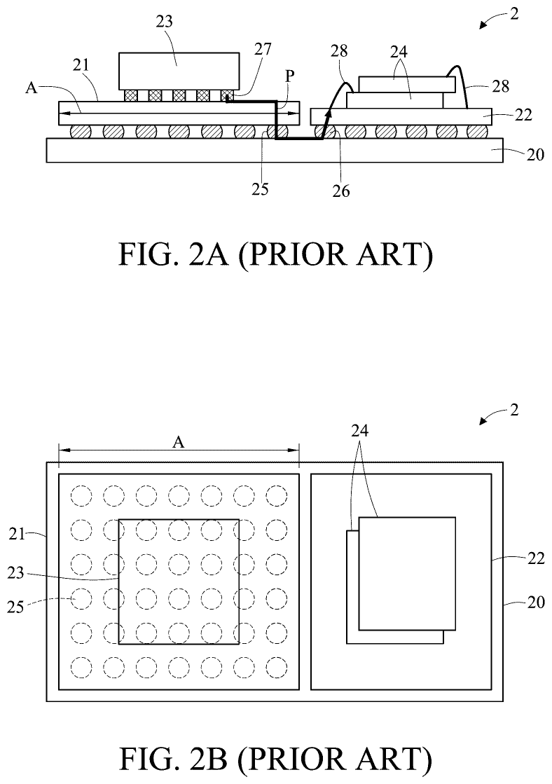

In summary, the electronic package 3 and the manufacturing method thereof of the present disclosure have at least the following features, advantages or technical effects.
1. The electronic package 3 of the present disclosure can be a side-by-side package structure and has the characteristics of low cost and easy assembly. It can also use the circuit board 50 with a low number of circuit layers.
2. In the manufacturing process of the side-by-side package structure 2 (see FIG. 2A and FIG. 2B) of the prior art, the solder balls 25 of larger size or pitch are all used to electrically connect the substrate 21 and the circuit board 20. As such, the substrate 21 would have a larger size (e.g., a length A), and the side-by-side package structure 2 would also have a larger overall size (e.g., volume). By contrast, during the manufacturing process of the electronic package 3 of the present disclosure (see FIG. 3F to FIG. 5), the bonding wires 36 with smaller sizes or pitches can be formed between the circuit layer 31 of the first substrate 30 and the first surface 50a of the circuit board 50 by a wire bonding method or a wire bonding (WB) process, which is beneficial for reducing the size of the first substrate 30 (e.g., a length B) and also reducing the overall size (e.g., volume) of the electronic package 3.
3. The side-by-side package structure 2 of the prior art (see FIG. 2A and FIG. 2B) uses the plurality of solder balls 25 for connection, which requires more solder balls 25 because there are more connection signals between the processor 23 and the memories 24, wherein each solder ball 25 requires a larger size or pitch, which will cause the size of the substrate 21 (e.g., a length A) to become larger, thus increasing the overall size and cost of the side-by-side package structure 2. By contrast, the electronic package 3 of the present disclosure (see FIG. 3F to FIG. 5) is partially connected by the plurality of bonding wires 36. Because the plurality of bonding wires 36 only require a smaller size or pitch (e.g., 50 microns), the required size of the first substrate 30 can be effectively reduced, thereby reducing the overall size and cost of the electronic package 3.
4. The plurality of solder balls 25 of the side-by-side package structure 2 (see FIG. 2A and FIG. 2B) of the prior art need to use larger sizes or pitches, and the signal pins connected to the plurality of solder balls 25 are more dispersed, and thus a larger number of circuit layers are required for the circuit board 20 (such as the carrier substrate) to complete the electrical connection between the processor 23 and the memory 24. By contrast, the size or pitch required for the plurality of bonding wires 36 of the electronic package 3 of the present disclosure (see FIG. 3F to FIG. 5) is smaller, so that the signals of the first electronic component 32 can be collectively brought out for electrical connection to the second electronic component 60. Therefore, the number of circuit layers of the circuit board 50 can be reduced, and the overall size (such as the overall height) of the electronic package 3 can be further reduced.
5. The electronic package 3 (See FIG. 3F to FIG. 5) of the present disclosure can use a wire bonding method or a wire bonding (WB) process to connect the signals of the first electronic component 32 (such as semiconductor chip/processor/application processor) to the circuit board 50 via the plurality of bonding wires 36 for further electrical connection to the second electronic component 60 (such as semiconductor chip/memory), so as to use the bonding wires 36 to replace the solder balls (the solder balls 25 in FIG. 2A and FIG. 2B) of the prior art. Accordingly, the present disclosure can reduce the size of the first substrate 30 (e.g., a length B), and can also reduce the overall size (e.g., volume) of the electronic package 3.
6. The present disclosure can form the heat dissipation member 70 (see FIG. 6 and FIG. 7) on the upper surface (such as the non-active surface) of the first electronic component 32, so as to use the heat dissipation member 70 to quickly dissipate the heat energy generated by the first electronic component 32 to the outside for heat dissipation or cooling.
7. The present disclosure can utilize the adhesion layer 80 (see FIG. 8) to quickly dissipate the heat energy generated by the first electronic component 32 and the second electronic component 60 to the outside for heat dissipation or cooling, or may use the adhesion layer 80 to effectively shield the signals generated by the first electronic component 32 and the second electronic component 60 to block the first electronic component 32 and the second electronic component 60 from external signal interference or electromagnetic interference (EMI).
8. The present disclosure can utilize the adhesion layer 80 (see FIG. 9) to quickly dissipate the heat energy generated by the first electronic component 32 to the outside for heat dissipation, or may use the adhesion layer 80 to effectively shield the signals generated by the first electronic component 32 and the second electronic component 60 to block the first electronic component 32 and the second electronic component 60 from signal interference or electromagnetic interference (EMI).
9. The present disclosure can dispose at least one (such as plural) passive element 43 (see FIG. 10 and FIG. 11) on the first side 30a of the first substrate 30, so as to increase the number of passive elements 43 by making good uses of the available area on the first side 30a of the first substrate 30.
10. The present disclosure can dispose the interposer 90 (see FIG. 12 and FIG. 13) between the first substrate 30 (the first electronic component 32) and the second electronic component 60, and then the plurality of bonding wires 36 are formed between the circuit layer 31 of the first substrate 30 and the upper surface of the interposer 90 by a wire bonding method or a wire bonding (WB) process. The upper surface of the interposer 90 can be lower or higher than the first side 30a (such as the upper surface) of the first substrate 30, the bonding wires 36 would not contact the solder balls 35 on the first surface 50a of the circuit board 50 or the materials of the solder balls 63 (such as tin materials), thereby adverse effects (such as tin material contamination or electrical short circuit) on the bonding wires 36 by the materials (such as tin materials) of the solder balls 35 or the solder balls 63 can be prevented.
11. In the manufacturing method of the electronic package 3 of the present disclosure, the existing technical problems in the industry can be solved using existing materials and machines, and thus no significant additional cost would be incurred.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a first substrate having a first side and a second side opposite to the first side;
a first electronic component disposed on the first side of the first substrate;
a circuit board having a first surface and a second surface opposite to the first surface, wherein the first substrate is disposed on the first surface of the circuit board, and wherein a plurality of bonding wires are formed on the first side of the first substrate for electrically connecting the first substrate to the circuit board;
a second electronic component disposed on the first surface of the circuit board, in a manner that the first electronic component is electrically connected to the second electronic component via the first substrate, the plurality of bonding wires and the circuit board in sequence; and
a first encapsulant formed on the first surface of the circuit board to encapsulate the first substrate, the first electronic component and the plurality of bonding wires.

2. The electronic package of claim 1, wherein an upper surface of the first encapsulant is higher than an upper surface of the first electronic component.

3. The electronic package of claim 1, wherein an upper surface of the first encapsulant is flush with or exposed from an upper surface of the first electronic component.

4. The electronic package of claim 1, further comprising a second substrate and a second encapsulant, wherein the second substrate is disposed on the first surface of the circuit board, the second electronic component is disposed on the second substrate, and the second encapsulant is formed on the second substrate to cover the second electronic component.

5. The electronic package of claim 1, further comprising a heat dissipation member formed on an upper surface of the first electronic component, wherein the first encapsulant further covers the heat dissipation member, and an upper surface of the heat dissipation member is flush with or exposed from an upper surface of the first encapsulant.

6. The electronic package of claim 1, further comprising an adhesion layer formed on an upper surface of the first electronic component, an upper surface of the second electronic component and an upper surface of the first encapsulant.

7. The electronic package of claim 1, further comprising an adhesion layer formed on an upper surface of the first electronic component and an upper surface of the first encapsulant.

8. The electronic package of claim 1, further comprising at least one passive element disposed on the first side or the second side of the first substrate.

9. The electronic package of claim 1, further comprising an interposer disposed on the first surface of the circuit board, wherein the plurality of bonding wires are formed between the first side of the first substrate and an upper surface of the interposer, and the upper surface of the interposer is lower than or higher than the first side of the first substrate.

10. The electronic package of claim 1, wherein the first encapsulant further covers the second electronic component.

11. A method of manufacturing an electronic package, comprising:
providing a first substrate having a first side and a second side opposite to the first side for a first electronic component to be disposed on the first side of the first substrate;
providing a circuit board having a first surface and a second surface opposite to the first surface for the first substrate to be disposed on the first surface of the circuit board, wherein a plurality of bonding wires are formed on the first side of the first substrate, and the first substrate is electrically connected to the circuit board via the plurality of bonding wires;
disposing a second electronic component on the first surface of the circuit board, and electrically connecting the first electronic component to the second electronic component via the first substrate, the plurality of bonding wires and the circuit board in sequence; and
forming a first encapsulant on the first surface of the circuit board to encapsulate the first substrate, the first electronic component and the plurality of bonding wires.

12. The method of claim 11, wherein an upper surface of the first encapsulant is higher than an upper surface of the first electronic component.

13. The method of claim 11, wherein an upper surface of the first encapsulant is flush with or exposed from an upper surface of the first electronic component.

14. The method of claim 11, further comprising disposing a second substrate on the first surface of the circuit board, disposing the second electronic component on the second substrate, and then forming a second encapsulant on the second substrate to encapsulate the second electronic component.

15. The method of claim 11, further comprising forming a heat dissipation member on an upper surface of the first electronic component, wherein the first encapsulant further encapsulates the heat dissipation member, and an upper surface of the heat dissipation member is flush with or exposed from an upper surface of the first encapsulant.

16. The method of claim 11, further comprising forming an adhesion layer on an upper surface of the first electronic component, an upper surface of the second electronic component and an upper surface of the first encapsulant.

17. The method of claim 11, further comprising forming an adhesion layer on an upper surface of the first electronic component and an upper surface of the first encapsulant.

18. The method of claim 11, further comprising disposing at least one passive element on the first side or the second side of the first substrate.

19. The method of claim 11, further comprising disposing an interposer on the first surface of the circuit board, wherein the plurality of bonding wires are formed between the first side of the first substrate and an upper surface of the interposer, and the upper surface of the interposer is lower than or higher than the first side of the first substrate.

20. The method of claim 11, wherein the first encapsulant further encapsulates the second electronic component.
